(19) United States
(12) Patent Application Publication
(10) Pub. No.: US 2013/0341780 A1
(43) Pub. Date: Dec. 26, 2013

(54) CHIP ARRANGEMENTS AND A METHOD FOR FORMING A CHIP ARRANGEMENT

(71) Applicants: Thorsten Scharf, Regensburg (DE); Boris Plikat, Tegernheim (DE); Henrik Ewe, Burglengenfeld (DE); Anton Prueckl, Schierling (DE); Stefan Landau, Wehrheim (DE)

(72) Inventors: Thorsten Scharf, Regensburg (DE); Boris Plikat, Tegernheim (DE); Henrik Ewe, Burglengenfeld (DE); Anton Prueckl, Schierling (DE); Stefan Landau, Wehrheim (DE)

(73) Assignee: INFINEON TECHNOLOGIES AG, Neubiberg (DE)

(21) Appl. No.: 13/527,668

(22) Filed: Jun. 20, 2012

(51) Int. Cl. H01L 23/48; H01L 21/60; H01L 23/495

(52) U.S. Cl. 257/677; 257/774; 257/741; 257/666; 438/124; 438/123; 257/E23.011; 257/E23.031; 257/E23.053; 257/E21.507

(57) ABSTRACT

A chip arrangement is provided. The chip arrangement including: a chip including at least one electrically conductive contact; a passivation material formed over the at least one electrically conductive contact; an encapsulation material formed over the passivation material; one or more holes formed through the encapsulation material and the passivation material, wherein the passivation material at least partially surrounds the one or more holes; and electrically conductive material provided within the one or more holes, wherein the electrically conductive material is electrically connected to the at least one electrically conductive contact.

### TECHNICAL FIELD

Various embodiments relate generally to chip arrangements and a method for forming a chip arrangement.

### BACKGROUND

Chip-embedding technology may include disposing a chip over a plate, e.g. a leadframe or a printed circuit board PCB, and adhering a mold or encapsulation material over the chip and to the plate. Usually, the plate, which may include copper, may be roughened, in order to improve the adhesion of the mold or encapsulation material to the plate. The roughening process however has a different effect on the plate than on the metallization layers of the chip. Normally, the roughening process has to take into account and compromise between providing sufficient strength to sufficiently roughen the plate, without destroying other components, such as the chip or chip metallization. Normally, the roughening process may not sufficiently roughen the plate, yet may destroy the chip front side or chip front side metallization. An “opened” i.e. exposed, electrically conductive contact 506 is shown in FIG. 5A. Passivation material 508 may be disposed over a part of electrically conductive contact 506, but a substantial portion of electrically conductive contact 506 is released, e.g. exposed, from passivation material 508. Chip 504 including electrically conductive contact 506 may optionally be disposed over plate 536. Regions of electrically conductive contact 506 and plate 536 may be exposed to a roughening process, wherein electrically conductive contact 506 may be at risk of being destroyed. Subsequently, as shown in FIG. 5B, encapsulation material 512 and one or more electrical interconnects 516 may be formed over chip 504.

### SUMMARY

Various embodiments provide a chip arrangement including: a chip including at least one electrically conductive contact; a passivation material formed over the at least one electrically conductive contact; an encapsulation material formed over the passivation material; one or more holes formed through the encapsulation material and the passivation material, wherein the passivation material at least partially surrounds the one or more holes; and electrically conductive material provided within the one or more holes, wherein the electrically conductive material is electrically connected to the at least one electrically conductive contact.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a chip arrangement according to an embodiment;

FIG. 2 shows a method for forming a chip arrangement according to an embodiment;

FIGS. 3A to 3E show a method for forming a chip arrangement according to an embodiment;

FIG. 3F shows a chip arrangement according to an embodiment;

FIG. 4 shows a chip arrangement according to an embodiment;

FIGS. 5A and 5B shows a chip arrangement according to an embodiment;

FIG. 6 shows a chip arrangement according to an embodiment;

FIG. 7 shows a chip arrangement according to an embodiment.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various embodiments provide a chip arrangement, wherein a passivation material may be provided over the entire surface of the chip.

Various embodiments provide a chip arrangement, wherein a passivation material may be provided over the entire surface of the chip contact metallization, except for the regions wherein via interconnects are provided over the contact metallization.

Various embodiments provide a method for forming a chip arrangement, wherein a chip surface and chip metallization may be protected from a roughening process to the lead frame.

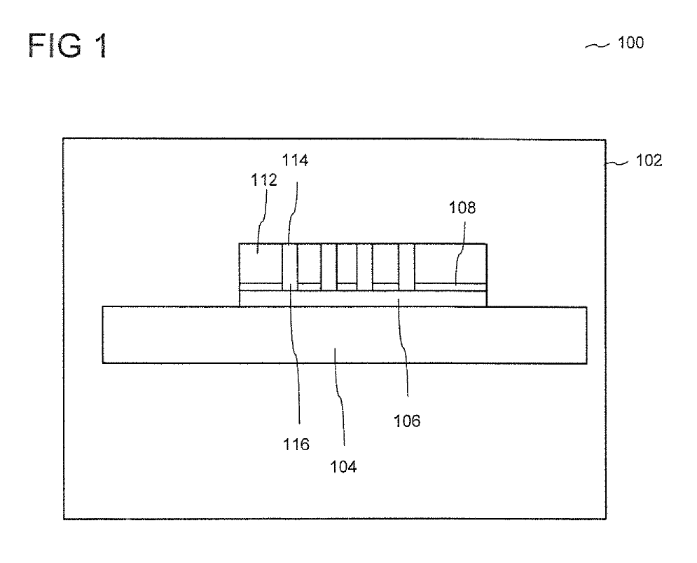

FIG. 1 shows chip arrangement 102 according to an embodiment.

Chip arrangement 102 may include chip 104 including at least one electrically conductive contact 106; passivation material 108 formed over at least one electrically conductive contact 106; encapsulation material 112 formed over passivation material 108; one or more holes 114 formed through encapsulation material 112 and passivation material 108, wherein passivation material 108 may at least partially surround one or more holes 114; and electrically conductive material 116 provided within the one or more holes 114, wherein electrically conductive material 116 may be electrically connected to at least one electrically conductive contact 106.

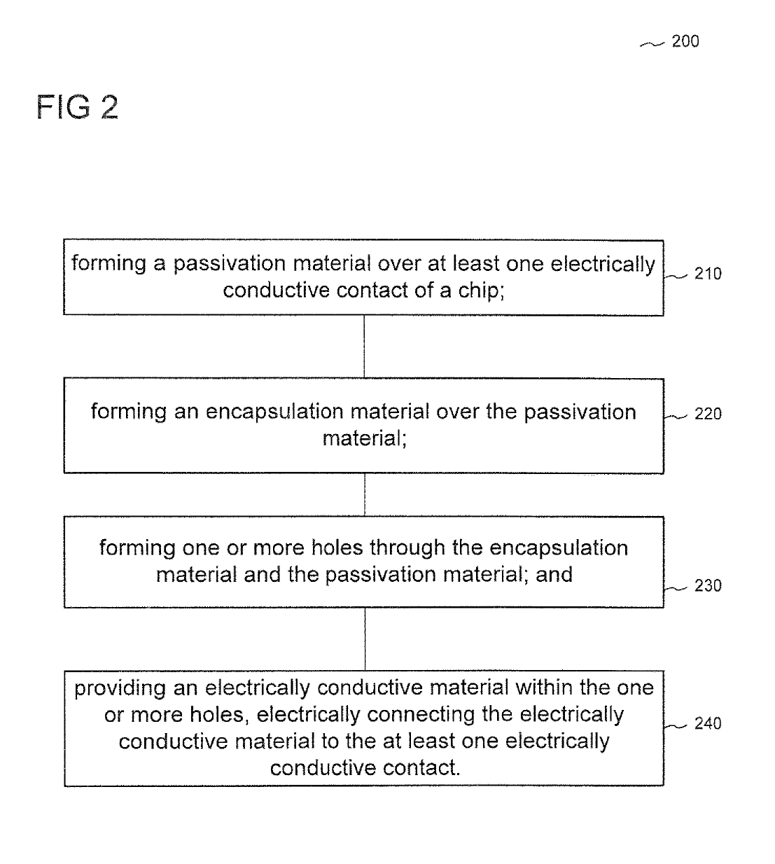

FIG. 2 shows method 200 for forming a chip arrangement according to an embodiment. Method 200 may include:

forming a passivation material over at least one electrically conductive contact of a chip (in 210);

forming an encapsulation material over the passivation material (in 220);

forming one or more holes through the encapsulation material and the passivation material (in 230); and

providing an electrically conductive material within the one or more holes, electrically connecting the electrically conductive material to the at least one electrically conductive contact (in 240).

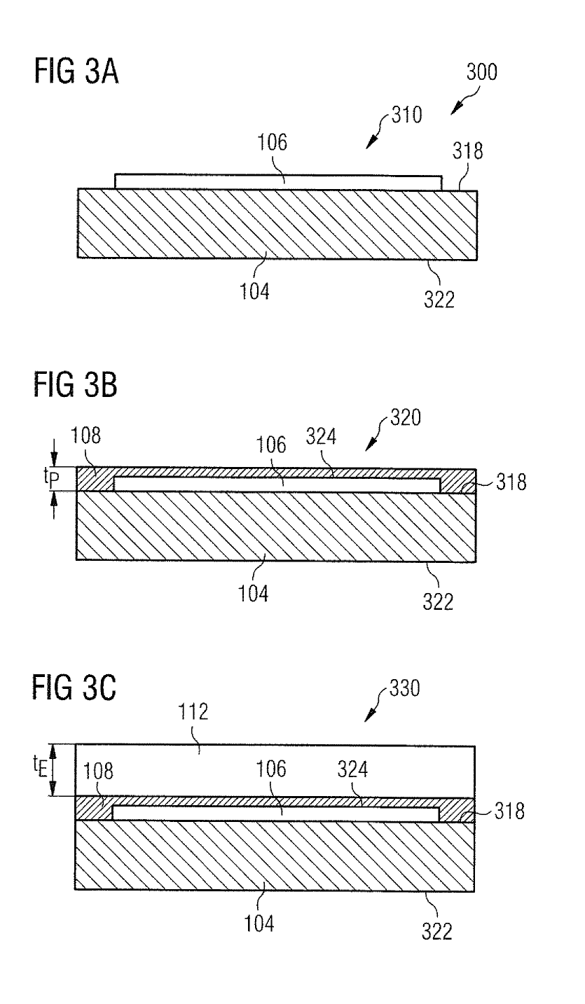

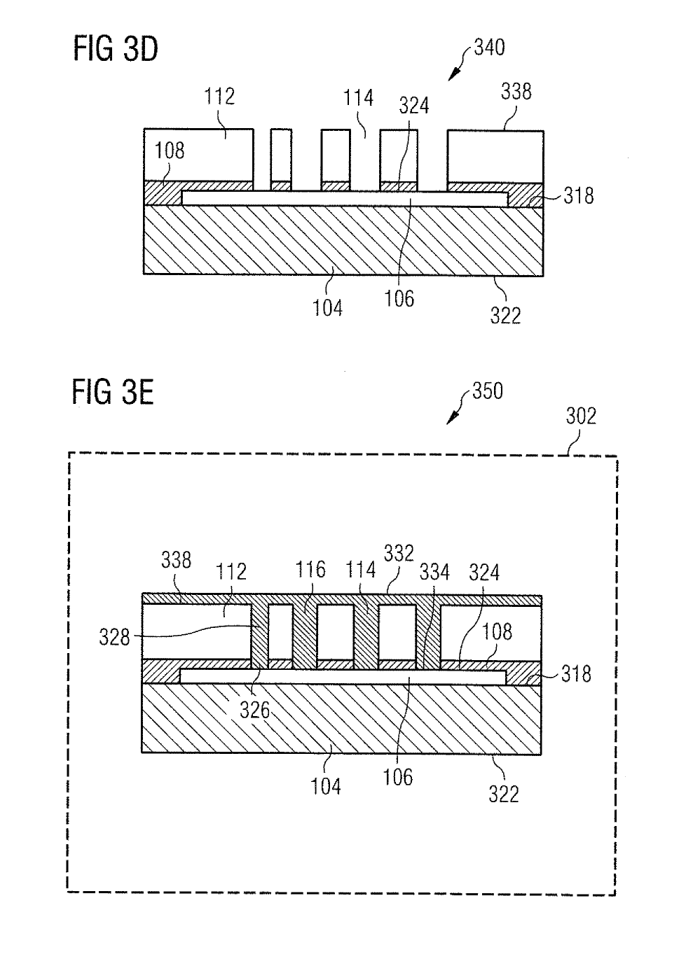

FIGS. 3A to 3E show method 300 for forming a chip arrangement, e.g. chip arrangement 102, e.g. chip arrangement 302, according to an embodiment. Method 300 may include one or more or all of the processes described with respect to method 200.

Chip 104 may include at least one electrically conductive contact 106. At least one electrically conductive contact 106 may be formed over chip top side 318. Chip 104 may include chip bottom side 322 which faces a direction opposite to a direction which chip top side 318 faces. At least one electrically conductive contact 106 may include electrically conductive contact 106 and further electrically conductive contacts 106a formed over chip top side 318. Only one electrically conductive contact 106 is shown in FIGS. 3A to 3E, however it may be understood that a chip 104 may include multiple electrically conductive contact pads, e.g. 106, 106A as shown in FIG. 3F. In other words, at least one electrically conductive contact 106 may not only include one electrically conductive contact 106 but may include more than one electrically conductive contact. For example, at least one electrically conductive contact may include a plurality of electrically conductive contacts. For example, electrically conductive contact 106 may include one, two, three, four, five, e.g. tens of electrical contacts formed over chip top side 318. Chip 104 may include a semiconductor chip, e.g. a semiconductor die.

Chip 104 may include a semiconductor integrated circuit logic chip. For example, chip 104 may include one or more logic devices, e.g. an application specific integrated chip ASIC, a driver, a controller, a sensor. Chip 104 may include a low power semiconductor device, e.g. devices capable of carrying up to 100 V to 150 V. Alternatively, chip 104 may include a power semiconductor chip, e.g. devices capable of carrying a voltage of up to approximately 600 V. For example, chip 104 may include a power device, e.g. a power transistor, a power thyristor, a power rectifier, a power diode.

Chip top side 318 may also be referred to as a “first side”, “front side” or “upper side” of the chip. The terms “top side”, “first side”, “front side” or “upper side” may be used interchangeably hereinafter. Chip bottom side 322 may also be referred to as “second side” or “back side” of the chip. The terms “second side”, “back side”, or “bottom side” may be used interchangeably hereinafter.

With respect to lower power semiconductor devices, chip top side 318 may be understood to refer to the side of the chip which carries one or more contact pads, or electrical contacts, wherein bonding pads or electrical connects may be attached; or wherein it is the side of the chip which may be mostly covered by metallization layers. Chip bottom side 322 may be understood to refer to the side of the chip which may be free from metallization or contact pads or electrical contacts.

With respect to power semiconductor devices, chip top side 318 may be understood to refer to the side of the chip which carries one or more contact pads, or electrical contacts, wherein bonding pads or electrical connects may be attached; or wherein it is the side of the chip which may be mostly covered by metallization layers. Chip bottom side 322 may be understood to refer to the side of the chip wherein typically at least one contact pad, or electrical contact may be formed, wherein the semiconductor power device may support a vertical current flow between chip top side 318 and chip bottom side 322.

At least one electrically conductive contact 106 may include at least one material, element or alloy from the following group of materials, the group consisting of: copper, aluminum, silver, tin, gold, zinc, nickel.

In 320, passivation material 108 may be formed over at least one electrically conductive contact 106 of chip 104. For example, passivation material 108 may be formed directly on at least one electrically conductive contact 106 of chip 104. Passivation material 108 may be deposited by at least one method from the following group of deposition methods, the group of deposition methods consisting of: sputtering, chemical vapor deposition, evaporation, plasma enhanced chemical vapor deposition, printing, oxidation, dip-coating, spin-coating. For example, plasma deposition may be used for depositing passivation material 108 including an oxide, e.g. silicon dioxide, or nitride, e.g. silicon nitride.

Passivation material 108 may have a thickness t_{P} ranging from about 1 nm to about 50 μm, e.g. about 5 nm to about 25 μm, e.g. about 5 nm to about 10 μm.

Passivation material 108 may cover surface 324 of at least one electrically conductive contact 106 and side of chip, e.g. top side 318 of chip 104 not covered by at least one electrically conductive contact 106. For example, passivation material 108 may be formed directly on surface 324, e.g. top surface of at least one electrically conductive contact 106 and directly on side of chip, e.g. top side 318 of chip 104 not covered by at least one electrically conductive contact 106.

Passivation material 108 may include an inorganic passivation, e.g. silicon nitride, silicon oxide, aluminum oxide, aluminum nitride. Inorganic passivation materials 108 may be deposited very thinly, down to approximately 1 nm. For example, passivation material 108 may include an organic passivation, e.g. polyimide, epoxy. For example, a combination of inorganic and organic passivation may be used. Passivation material 108 may include at least one from the following group of materials, the group of materials consisting of: polyimide, epoxy, silicon nitride, silicon oxide, aluminum oxide, aluminum nitride.

According to various embodiments, passivation material 108 may cover entire surface 324 of at least one electrically conductive contact 106. According to various embodiments, passivation material 108 may cover partially surface 324 of at least one electrically conductive contact 106. According to various embodiments, passivation material 108 may cover entire top side 318 of chip 104. According to various embodiments, passivation material 108 may cover partially top side 318 of chip 104. Passivation material 108 may be formed such that a continuous layer of passivation material 108 may be formed over electrical contact 106. In other words, passivation material 108 may not be opened, and may not expose any regions of electrical contact 106 and/or any regions of top side 318 of chip 104. Passivation material 108 may not be removed, even after subsequent bonding process and, may remain in chip arrangement 102, whereby it additionally, increases the robustness of the chip arrangement.

In 330, encapsulation material 112 may be formed over passivation material 108.

Encapsulation material 112 may be formed over at least one electrically conductive contact 106 and side of chip, e.g. top side 318 of chip 104 not covered by at least one electrically conductive contact 106. Passivation material 108 may be arranged between encapsulation layer and top side 318 of chip 104. Passivation material 108 may be arranged between encapsulation layer and at least one electrically conductive contact 106.

According to various embodiments, encapsulation material 112 may be formed over an entire surface 324 of at least one electrically conductive contact 106. According to various embodiments, encapsulation material 112 may be formed over an entire top side 318 of chip 104.

Encapsulation material 112 may have a thickness t_{E} ranging from about 10 μm to about 300 μm, e.g. about 20 μm to about 200 μm, e.g. about 30 μm to about 100 μm.

Encapsulation material 112 may include at least one from the following group of materials, the group consisting of: an electrically insulating material, filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

In 340, one or more holes 114 may be formed through encapsulation material 112 and passivation material 108. A hole 114 may be referred to as a through-hole formed through both encapsulation material 112 and passivation material 108. One or more holes 114 may each include a blind via, e.g. a hole that is exposed only on one side of the chip arrangement 302. For example, one or more holes 114 may be exposed only at encapsulation material top side 338.

One or more holes 114, e.g. via holes, may be formed, e.g. through a laser drilling process. Laser drilling may create one or more holes 114 through encapsulation material 112 and passivation material 108. Alternatively, mechanical drilling may be carried out to create one or more holes 114 through encapsulation material 112 and passivation material 108. During the opening of one or more holes 114, e.g. microvias, passivation 108 may be locally opened through the laser drilling process. It may be understood that at least one electrically conductive contact 106 may not be exposed until subsequently, perforations through passivation material 108 are successfully made in necessary locations. Furthermore, adhesion of encapsulation material 112 may occur over the chip, e.g. directly on passivation material 108, and no longer directly on at least one electrically conductive contact 106, i.e. the chip metallization, and/or no longer directly on chip top side 318. Adhesion of encapsulation material 112 to passivation material 108 is of a high standard, and no dedicated bonding process, which may normally be challenging, may be required, e.g. to adhere encapsulation material 112 to chip metallization. One or more holes 114, i.e. contact holes, may be provided with electrically conductive material 116, e.g. metal, to provide an electrical interconnect and/or a redistribution layer.

Wherein passivation material 108 may include an inorganic material, e.g. silicon oxide, e.g. silicon nitride, e.g. aluminum oxide, e.g. aluminum nitride, or an organic material, e.g. polyimide, e.g. epoxy, the laser process may be accordingly adapted. For example, adapted with respect to at least one of laser power and aperture focus. According to various embodiments, the formation of the one or more holes 114 may be carried out according to different laser drilling steps, e.g. with different laser sources, for passivation material 108 which may include a combination of organic and inorganic materials. According to alternative embodiments, laser drilling may be combined with mechanical drilling to form the one or more holes 114. Optionally, one or more holes 114 may be subjected to a modified chemical cleaning, before process 350. Cleaning of one or more holes 114 may be carried out via plasma cleaning and/or wet chemical cleaning.

In 350, electrically conductive material 116 may be provided within one or more holes 114, electrically connecting electrically conductive material 116 to at least one electrically conductive contact 106. At least portion 326 of electrically conductive material 116 may directly contact passivation material 108; and at least further portion 328 of electrically conductive material 116 may directly contact encapsulation material 112. Portion 326 and further portion 328 may include electrically conductive material 116 formed within one or more holes 114.

Passivation material 108 formed between one or more holes 114 may directly contact electrically conductive material 116 provided within one or more holes 114. Passivation material 108 may substantially cover surface 324 of at least one electrically conductive contact 106 except in regions 334 wherein electrically conductive material 116 may be electrically connected to at least one electrically conductive contact 106. For example, passivation material 108 may entirely cover surface 324 of at least one electrically conductive contact 106 except in regions 334 wherein electrically conductive material 116 may be electrically connected to at least one electrically conductive contact 106. Passivation material 108 may at least partially surround one or more holes 114 and cover side 318 of chip 104 not covered by at least one electrically conductive contact 106.

Electrically conductive material 116 may include at least one material, element or alloy from the following group of materials, the group consisting of: copper, aluminum, silver, tin, gold, zinc, nickel.

Providing electrically conductive material 116 within one or more holes 114 may include at least one of filling one or more holes 114 with electrically conductive material 116 and growing electrically conductive material 116 within one or more holes 114.

Filling one or more holes 114 with electrically conductive material 116 may include depositing electrically conductive material 116 using galvanic filling, electroplating, printing of electrically conductive pastes. Growing electrically conductive material 116 within one or more holes 114 may include deposition of structures, e.g. nanostructures and/or microstructures. Microstructures may include, e.g. microfibers, microtubes, microwires. Nanostructures may include, e.g. nanotubes, nanowires, nanoparticles. Microstructures may be deposited using electrochemical deposition and/or chemical vapor deposition and/or plasma enhanced chemical vapor deposition.

At least part of electrically conductive material 116, e.g. region 332 may be formed over encapsulation material 112. For example, region 332 of electrically conductive material 116 may be formed over encapsulation material top side 338. Encapsulation material top side 338 may face a same direction as that faced by chip top side 318.

Region 332 of electrically conductive material 116 may be subjected to further processes, for example, region 332 may include a redistribution layer, and may undergo selective removal, e.g. selective etching, to selectively remove one or more portions of region 332. Further redistribution layers (not shown) may be applied over region 332, which may be electrically connected to electrically conductive material 116, e.g. region 332.

According to various embodiments, region 332 of electrically conductive material 116 may subsequently be electrically connected to a further chip (not shown). According to various embodiments, region 332 of electrically conductive material 116 may subsequently be electrically connected to a printed circuit board. According to various embodiments, region 332 of electrically conductive material 116 may subsequently be electrically connected to another at least one electrically conductive contact 106, e.g. one or more further electrically conductive contacts, e.g. contact pads, 106a formed over chip 104 (as shown in chip arrangement 302a of FIG. 3F).

According to another embodiment, chip 104 may be disposed over chip carrier 336 (See FIG. 3F). According to another embodiment, chip 104 may be disposed over chip carrier 336 before process 320, i.e. before forming passivation material 108. According to another embodiment, chip 104 may be disposed over chip carrier 336 after process 320, i.e. after forming passivation material 108. Chip carrier 336 may include at least one from the following group of materials, the group consisting of: copper, nickel, iron, copper alloy, nickel alloy, iron alloy. Chip carrier 336 may include a printed circuit board. Chip carrier 336 may include a lead frame, the lead frame including at least one from the following group of materials, the group consisting of: copper, nickel, iron, copper alloy, nickel alloy, iron alloy. Chip carrier 336 may include a printed circuit board.

Chip 104 may be adhered to chip carrier 336 via chip bottom side 322. For example, if chip 104 included a power device, chip 104 may be electrically connected to chip carrier 336 via at least one contact pad formed over chip bottom side 322, e.g. by soft solder, hard solder, diffusion solder, e.g. electrically conductive glue. Each electrically conductive contact pad may include at least one material, element or alloy from the following group of materials, the group consisting of: copper, aluminum, silver, tin, gold, zinc, nickel, titanium, tungsten. For example, if chip 104 included a lower power logic device, chip 104 may be adhered via chip bottom side 322 to chip carrier 336 by an electrically insulating medium, e.g. an adhesive, an electrically insulating adhesive, an epoxy, a glue, a paste, an adhesive foil, an adhesive film.

According to an embodiment, chip 104 may be disposed over chip carrier 336 after process 320. In other words, chip 104 may be disposed over chip carrier 336 after passivation material 108 is formed over chip top side 318. In this case, passivation material 108 may not be formed over chip carrier 336, therefore, only one type of copper surface, i.e. chip carrier top side 342 leadframe, may be exposed and may need to be bonded directly to encapsulation material 112, therefore simplifying the bonding process. Furthermore, only one type of copper surface, i.e. top side 342 of chip carrier 336 may be exposed to a roughening process. According to various embodiments, chip 104 may be disposed over chip carrier 336 before process 320, e.g. before deposition of passivation material 108. In which case, process 320 may be adapted to process 420 wherein passivation material 108 may be formed directly on chip carrier 336 in addition to being formed over chip 104. Furthermore, at least one of passivation material 108 and encapsulation material 112 may further be formed over chip carrier 336, e.g. top side 342 of chip carrier 336, which is the side which chip bottom side 322 may be adhered to. Top side 342 of chip carrier 336 may face the same direction as that which top side 318 of chip 104 faces. Process 420 may include one or more or all of the features and/or processes and/or basic functionalities of the features described with respect to process 320. A roughening process may be optionally performed on chip carrier 336, e.g. a copper lead frame, after forming passivation material 108 (in process 420). The roughening process may include etching, e.g. chemical and/or plasma etching, one or more surfaces of chip carrier 336 including chip carrier top side 342, to improve adhesion of encapsulation material 112 to chip carrier 336, e.g. chip carrier top side 342.

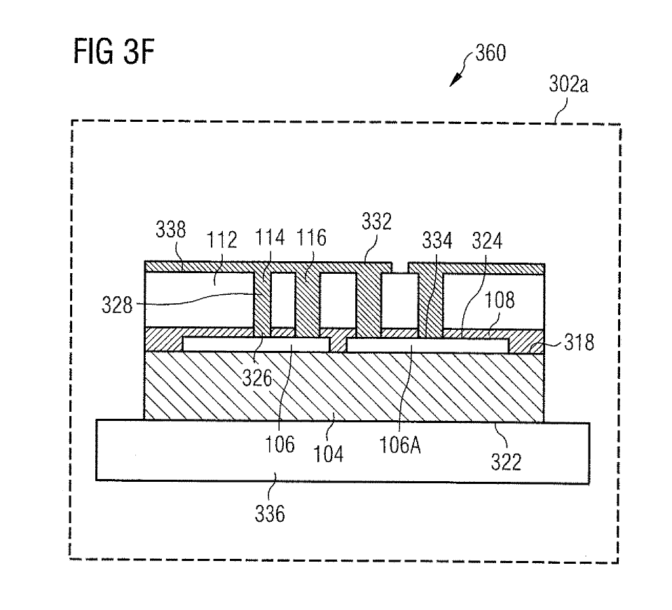

Subsequently, process 330 may be adapted to process 430 and process 430 may be carried out. Process 430 may include one or more or all of the features and/or processes and/or basic functionalities of the features described with respect to process 330. Furthermore, encapsulation material 112 may be further formed over chip carrier 336, e.g. over chip carrier side 342. Encapsulation material 112 may at least partially surround one or more lateral sides 344, 346 of chip 104 (See chip arrangement 402 in FIG. 4).

It may be understood that the roughening process may be performed on chip carrier after forming passivation material 108 (in 420) and before forming encapsulation material 112 (in 430).

FIG. 4 shows chip arrangement 402 according to an embodiment.

Chip arrangement 402, e.g. a chip package, may include chip 104 including at least one electrically conductive contact 106 (e.g. electrically conductive contact 106, electrically conductive contact 106a, etc); passivation material 108 formed over at least one electrically conductive contact 106; encapsulation material 112 formed over passivation material 108; one or more holes 114 formed through encapsulation material 112 and passivation material 108, wherein passivation material 108 at least partially surrounds one or more holes 114; and electrically conductive material 116 provided within one or more holes 114, wherein electrically conductive material 116 may be electrically connected to at least one electrically conductive contact 106.

Passivation material 108 may include at least one from the following group of materials, the group of materials consisting of: polyimide, epoxy, silicon nitride, silicon oxide, aluminum oxide, aluminum nitride.

Encapsulation material 112 may include at least one from the following group of materials, the group consisting of: an electrically insulating material, filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

Passivation material 108 may have a thickness t_{P} ranging from about 1 nm to about 50 μm, e.g. about 5 nm to about 25 μm, e.g. about 5 nm to about 10 μm.

Encapsulation material 112 may have a thickness ranging from about 10 μm to about 300 μm.

Passivation material 108 may cover surface 324 of at least one electrically conductive contact 106 and side of chip, e.g. top side 318 of chip 104 not covered by at least one electrically conductive contact 106.

At least portion 326 of electrically conductive material 116 directly contacts passivation material 108; and at least further portion 328 of electrically conductive material 116 directly contacts encapsulation material 112.

Passivation material 108 formed between one or more holes 114 may directly contact electrically conductive material 116 provided within the one or more holes 114.

Electrically conductive material 116 may include at least one material, element or alloy from the following group of materials, the group consisting of: copper, aluminum, silver, tin, gold, zinc, nickel.

At least part 332 of electrically conductive material 116 may be formed over encapsulation material 112.

Chip 104 may be disposed over chip carrier 336; and at least one of passivation material 108 and encapsulation material 112 may be formed over chip carrier 336.

Chip carrier 336 may include a lead frame, the lead frame including at least one from the following group of materials, the group consisting of: copper, nickel, iron, copper alloy, nickel alloy, iron alloy.

Chip arrangement 402 may include chip 104 including at least one electrically conductive contact 106; passivation material 108 formed over at least one electrically conductive contact 106; encapsulation material 112 formed over passivation material 108; one or more holes 114 formed through encapsulation material 112 and passivation material 108, wherein electrically conductive material 116 provided within one or more holes 114; wherein passivation material 108 substantially covers surface 324 of at least one electrically conductive contact 106 except in regions 334 wherein electrically conductive material 116 is electrically connected to at least one electrically conductive contact 106.

Passivation material 108 may at least partially surround one or more holes 114 and cover side 318 of chip 104 not covered by at least one electrically conductive contact 106.

It may be understood that although only one electrically conductive contact 106 is shown disposed over chip top side 318, further electrically conductive contacts 106a, as described according to FIG. 3F (not shown) may also be disposed over chip top side 318.

Various embodiments provides a chip arrangement, e.g. chip arrangement 102, e.g. chip arrangement 302, e.g. chip arrangement 402, wherein at least one electrically conductive contact 106 may be substantially, e.g. completely, covered by passivation material, and subsequently embedded in a chip embedded housing.

Various embodiments provide a chip arrangement, wherein at least one electrically conductive contact 106 may be substantially, but not entirely, covered by passivation material 108, e.g. passivation material 108 may expose one or more regions of electrically conductive 106, e.g. to roughening, or for other purposes.

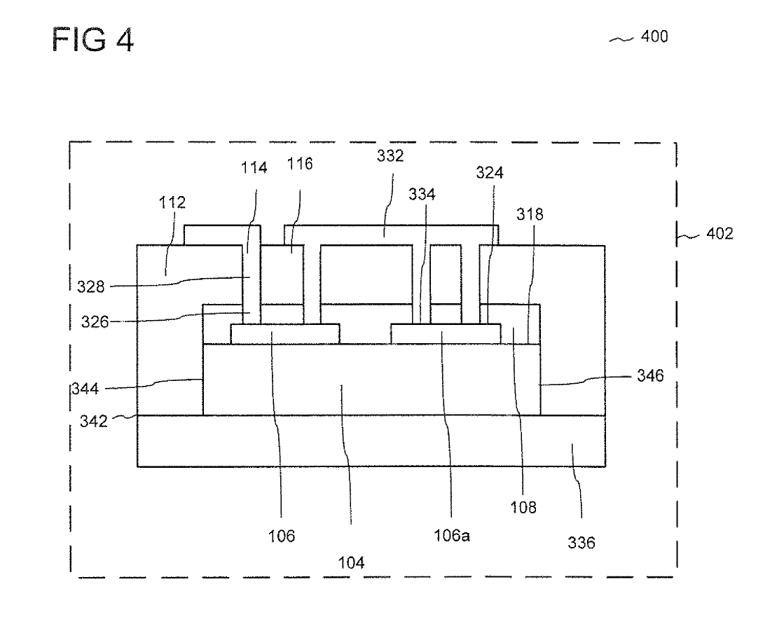

FIG. 5B shows chip arrangement 502 including the “opened” electrically conductive contact 506 of FIG. 5A. One or more holes 514 may be formed only through encapsulation material 512 and not passivation material 508. Encapsulation material 512 may be formed directly onto electrically conductive contact 506. Furthermore, electrically conductive contact 506 may be exposed to chemical processes, e.g. roughening processes, wherein during the roughening process, it may not be protected from destruction. Furthermore, the roughening process, which may be carried out may in addition not be optimized, but instead carried out at a compromised level, wherein the roughening process may have insufficient roughening strength to sufficiently roughen a chip carrier to produce sufficiently high standards of adhesion to encapsulation material 512. Furthermore, the roughening process at compromised levels may nevertheless still damage chip 504 and/or chip electrically conductive contact 506.

Although the chip arrangements 102, 302, 402, described thus far have described a chip arrangement including a single chip 104, it may be understood that according to various embodiments, the chip arrangements 102, 302, 402, may include more than one chip 104.

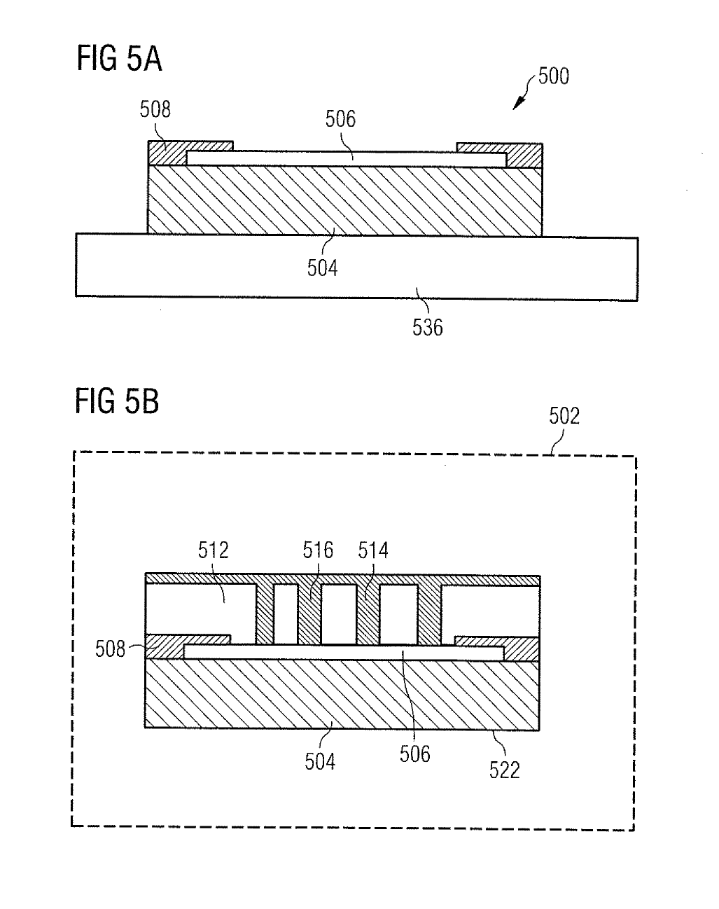

As shown in FIG. 6, chip arrangement 602, e.g. a chip package, may include one or more chips 104, 104₁, 104₂, etc. of at least one of chip arrangements 102, 302, 402 (See FIG. 6). For example, one or more chips 104, 104₁ may be formed over chip carrier 336, e.g. over chip carrier top side 342. According to various other embodiments, one or more chips 104₂, 104₃ may be formed over chip carrier 336, e.g. over chip carrier bottom side 648, wherein chip carrier bottom side 648 may face a direction substantially opposite to a direction which chip carrier top side 342 faces. Similarly to method 300, chip bottom side 648 may be roughened in a process similar to the roughening process of chip carrier top side 342, so that adhesion of encapsulation material 612 to chip carrier bottom side 648 may be improved. One or more holes, e.g. 114₃, e.g. 114₄ may be formed through passivation material, e.g. 108₃, e.g. 108₄ and encapsulation material 612.

According to various embodiments, at least one chip from one or more chips 104, 104₁, 104₂, may be provided with “full passivation”, wherein passivation material 108 covers entire surface 324 of at least one electrically conductive contact 106, as shown in chip arrangement 402 in FIG. 4, and manufactured according to at one or more or all processes described with respect to method 300.

According to various embodiments, chip arrangement 602 (See FIG. 6) may include at least one chip arrangement 102, 302, 402 including one chip 104 provided with “full passivation” as shown in FIG. 4 and at least one other chip arrangement 102, 302, 402 including one chip 104₁ provided with “full passivation” as shown in FIG. 4 and manufactured according to at one or more or all processes described with respect to method 300.

According to various embodiments, at least one of the one or more chips 104, 104₁, 104₂, etc may include a power semiconductor chip. According to various embodiments, at least one of the one or more chips 104, 104₁, 104₂, etc may include a semiconductor logic chip. According to various embodiments, chip arrangement may include at least one semiconductor logic chip and at least one semiconductor power chip.

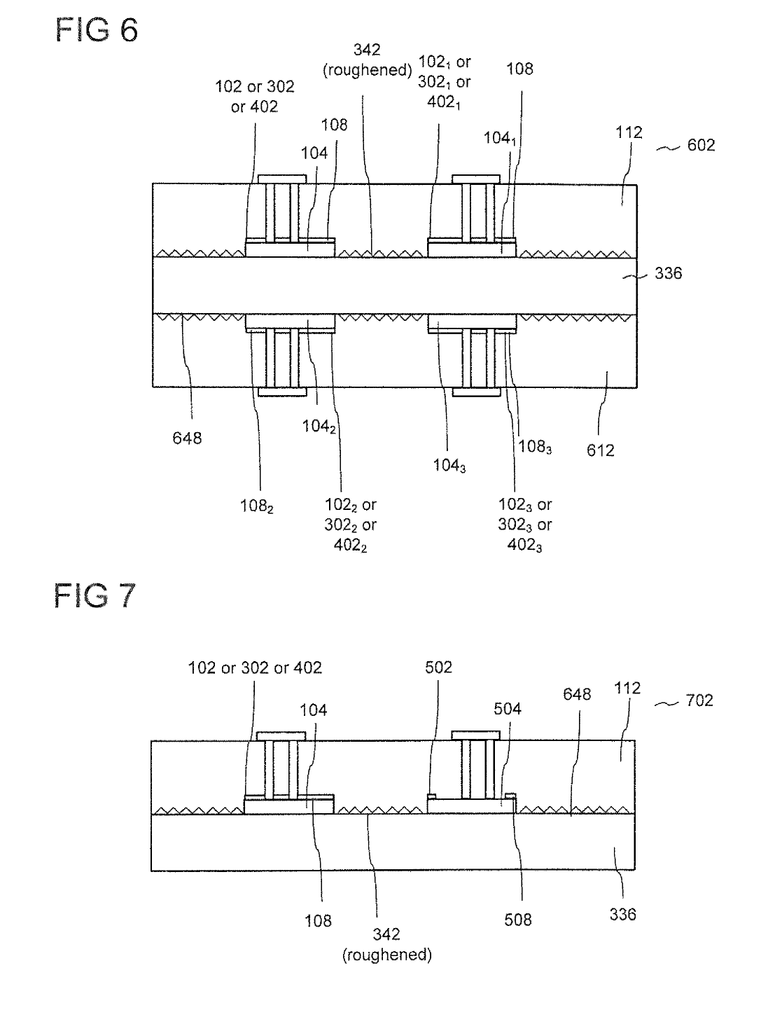

According to various embodiments, chip arrangement 702 (See FIG. 7) may include at least one chip arrangement 102, 302, 402 including one or more chips 104, 104₁, 104₂, etc provided with “full passivation” as shown in FIG. 4 and at least one other chip arrangement 502 including an “open contact” chip 504 as shown in FIG. 5.

Wherein one or more chips 104, 104₁, 104₂, etc may be formed over chip carrier 336, encapsulation material 112, 112₁, 112₂ etc may be formed over one or more chips 104, 104₁, 104₂, etc in a single process. Encapsulation material 112 may adhere one or more chips 104, 104₁, 104₂, etc to chip carrier 336, for example, to chip top side 342. It may be understood that similarly to various embodiments described with respect to FIG. 6, one or more chips may be formed over the chip top side 342 and/or chip bottom side 648.

Wherein one or more chips 104, 104₁, 104₂, etc may be formed over chip carrier 336, and wherein at least one chip from one or more chips 104, 104₁, 104₂, etc includes chip 404 with “full passivation” and at least one other chip includes “open contact” chip 504, encapsulation material 112, 512 may be formed over one or more chips 104, 504 in a single process. Encapsulation material 112, 512 may adhere one or more chips 104, 504 to chip carrier 336. (See FIG. 7)

Various embodiments provide a chip arrangement including: a chip including at least one electrically conductive contact; a passivation material formed over the at least one electrically conductive contact; an encapsulation material formed over the passivation material; one or more holes formed through the encapsulation material and the passivation material, wherein the passivation material at least partially surrounds the one or more holes; electrically conductive material provided within the one or more holes, wherein the electrically conductive material is electrically connected to the at least one electrically conductive contact.

According to an embodiment, the passivation material includes at least one from the following group of materials, the group of materials consisting of: polyimide, epoxy, silicon nitride, silicon oxide.

According to an embodiment, the encapsulation material includes at least one from the following group of materials, the group consisting of: an electrically insulating material, filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

According to an embodiment, the passivation material includes a thickness ranging from about 1 nm to about 50 μm.

According to an embodiment, the encapsulation material includes a thickness ranging from about 10 μm to about 300 μm.

According to an embodiment, the passivation material covers a surface of the at least one electrically conductive contact and a side of the chip not covered by the at least one electrically conductive contact.

According to an embodiment, at least a portion of the electrically conductive material directly contacts the passivation material; and at least a further portion of the electrically conductive material directly contacts the encapsulation material.

According to an embodiment, the passivation material formed between the one or more holes directly contacts the electrically conductive material filling the one or more holes.

According to an embodiment, the electrically conductive material includes at least one material, element or alloy from the following group of materials, the group consisting of: copper, aluminum, silver, tin, gold, zinc, nickel.

According to an embodiment, at least part of the electrically conductive material is formed over the encapsulation material.

According to an embodiment, the chip is disposed over a chip carrier; and at least one of the passivation material and the encapsulation material is formed over the chip carrier.

According to an embodiment, the chip carrier includes a lead frame, the lead frame including at least one from the following group of materials, the group consisting of: copper, nickel, iron, copper alloy, nickel alloy, iron alloy.

According to an embodiment, the chip carrier includes a printed circuit board PCB or a direct copper bonded DCB substrate.

According to an embodiment, the at least one electrically conductive contact includes a plurality of electrically conductive contacts. Various embodiments provide a chip arrangement including: a chip including at least one electrically conductive contact; a passivation material formed over the at least one electrically conductive contact; an encapsulation material formed over the passivation material; one or more holes formed through the encapsulation material and the passivation material, electrically conductive material provided within the one or more holes; wherein the passivation material substantially covers a surface of the at least one electrically conductive contact except in regions wherein the electrically conductive material is electrically connected to the at least one electrically conductive contact.

According to an embodiment, the passivation material includes at least one from the following group of materials, the group of materials consisting of: polyimide, epoxy, silicon nitride, silicon oxide, aluminum oxide, aluminum nitride.

According to an embodiment, the encapsulation material includes at least one from the following group of materials, the group consisting of: an electrically insulating material, filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

According to an embodiment, the passivation material at least partially surrounds the one or more holes and covers a side of the chip not covered by the at least one electrically conductive contact.

According to an embodiment, at least a portion of the electrically conductive material directly contacts the passivation material; and at least a further portion of the electrically conductive material directly contacts the encapsulation material.

According to an embodiment, the electrically conductive material includes at least one from the following group of materials, the group consisting of: copper, aluminum, silver, tin, gold, zinc, nickel, and an alloy of one or more materials of the group.

According to an embodiment, the chip is disposed over a chip carrier; and wherein at least one of the passivation material and encapsulation material is formed over the chip carrier.

According to an embodiment, the chip carrier includes a lead frame, the lead frame including at least one from the following group of materials, the group consisting of: copper, nickel, iron, copper alloy, nickel alloy, iron alloy.

According to an embodiment, the chip carrier includes a printed circuit board or a direct copper bonded substrate.

Various embodiments provide a method for forming a chip arrangement, the method including: forming a passivation material over at least one electrically conductive contact of a chip; forming an encapsulation material over the passivation material; forming one or more holes through the encapsulation material and the passivation material; and providing an electrically conductive material within the one or more holes, electrically connecting the electrically conductive material to the at least one electrically conductive contact.

According to an embodiment, the method further includes disposing the chip over a chip carrier before or after forming the passivation material over at least one electrically conductive contact of a chip.

According to an embodiment, the method further includes performing a roughening process on the chip carrier after forming the passivation material and before forming the encapsulation material over the passivation material.

According to an embodiment, forming one or more holes through the encapsulation material and the passivation material includes forming one or more holes through the encapsulation material and the passivation material by at least one method from the following group of methods, the group consisting of: laser drilling and mechanical drilling.

According to an embodiment, providing an electrically conductive material within the one or more holes includes at least one of filling the one or more holes with electrically conductive material and growing electrically conductive material within the one or more holes.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip arrangement comprising:
a chip comprising at least one electrically conductive contact;
a passivation material formed over the at least one electrically conductive contact;
an encapsulation material formed over the passivation material;
one or more holes formed through the encapsulation material and the passivation material, wherein the passivation material at least partially surrounds the one or more holes;
electrically conductive material provided within the one or more holes, wherein the electrically conductive material is electrically connected to the at least one electrically conductive contact.

2. The chip arrangement according to claim 1,
wherein the passivation material comprises at least one from the following group of materials, the group of materials consisting of: polyimide, epoxy, silicon nitride, silicon oxide, aluminum oxide, aluminum nitride.

3. The chip arrangement according to claim 1,
wherein the encapsulation material comprises at least one from the following group of materials, the group consisting of: an electrically insulating material, filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

4. The chip arrangement according to claim 1,
wherein the passivation material comprises a thickness ranging from about 1 nm to about 50 μm.

5. The chip arrangement according to claim 1,
wherein the encapsulation material comprises a thickness ranging from about 10 μm to about 300 μm.

6. The chip arrangement according to claim 1,
wherein the passivation material covers a surface of the at least one electrically conductive contact and a side of the chip not covered by the at least one electrically conductive contact.

7. The chip arrangement according to claim 1,
wherein at least a portion of the electrically conductive material directly contacts the passivation material; and
wherein at least a further portion of the electrically conductive material directly contacts the encapsulation material.

8. The chip arrangement according to claim 1,
wherein the passivation material formed between the one or more holes directly contacts the electrically conductive material filling the one or more holes.

9. The chip arrangement according to claim 1,
wherein the electrically conductive material comprises at least one material, element or alloy from the following group of materials, the group consisting of: copper, aluminum, silver, tin, gold, zinc, nickel.

10. The chip arrangement according to claim 1,
wherein at least part of the electrically conductive material is formed over the encapsulation material.

11. The chip arrangement according to claim 1,
wherein the chip is disposed over a chip carrier; and
wherein at least one of the passivation material and the encapsulation material is formed over the chip carrier.

12. The chip arrangement according to claim 11,
wherein the chip carrier comprises a lead frame, the lead frame comprising at least one from the following group of materials, the group consisting of: copper, nickel, iron, copper alloy, nickel alloy, iron alloy.

13. The chip arrangement according to claim 11,
wherein the chip carrier comprises a printed circuit board or a direct copper bonded substrate.

14. The chip arrangement according to claim 1,
wherein the at least one electrically conductive contact is a plurality of electrically conductive contacts.

15. A chip arrangement comprising:
a chip comprising at least one electrically conductive contact;
a passivation material formed over the at least one electrically conductive contact;
an encapsulation material formed over the passivation material;
one or more holes formed through the encapsulation material and the passivation material, wherein the one or more holes are filled with electrically conductive material electrically connected to the at least one electrically conductive contact;
wherein the passivation material substantially covers a surface of the at least one electrically conductive contact except in regions wherein the electrically conductive material is electrically connected to the at least one electrically conductive contact.

16. The chip arrangement according to claim 15,
wherein the passivation material comprises at least one from the following group of materials, the group of materials consisting of: polyimide, epoxy, silicon nitride, silicon oxide, aluminum oxide, aluminum nitride.

17. The chip arrangement according to claim 15,
wherein the encapsulation material comprises at least one from the following group of materials, the group consisting of: an electrically insulating material, filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

18. The chip arrangement according to claim 15,
wherein the passivation material at least partially surrounds the one or more holes and covers a side of the chip not covered by the at least one electrically conductive contact.

19. The chip arrangement according to claim 15,
wherein at least a portion of the electrically conductive material directly contacts the passivation material; and
wherein at least a further portion of the electrically conductive material directly contacts the encapsulation material.

20. The chip arrangement according to claim 15,
wherein the electrically conductive material comprises at least one from the following group of materials, the group consisting of: copper, aluminum, silver, tin, gold, zinc, nickel, and an alloy of one or more materials of the group.

21. The chip arrangement according to claim 15,
wherein the chip is disposed over a chip carrier; and
wherein at least one of the passivation material and encapsulation material is formed over the chip carrier.

22. The chip arrangement according to claim 21,
wherein the chip carrier comprises a lead frame, the lead frame comprising at least one from the following group of materials, the group consisting of: copper, nickel, iron, copper alloy, nickel alloy, iron alloy.

23. The chip arrangement according to claim 21,
wherein the chip carrier comprises a printed circuit board or a direct copper bonded substrate.

24. A method for forming a chip arrangement, the method comprising:
forming a passivation material over at least one electrically conductive contact of a chip;
forming an encapsulation material over the passivation material;
forming one or more holes through the encapsulation material and the passivation material; and
providing an electrically conductive material within the one or more holes, electrically connecting the electrically conductive material to the at least one electrically conductive contact.

25. The method according to claim 24, further comprising
disposing the chip over a chip carrier before or after forming the passivation material over at least one electrically conductive contact of a chip.

26. The method according to claim 24, further comprising
performing a roughening process on the chip carrier after forming the passivation material and before forming the encapsulation material over the passivation material.

27. The method according to claim 24,
wherein forming one or more holes through the encapsulation material and the passivation material comprises forming one or more holes through the encapsulation material and the passivation material by at least one method from the following group of methods, the group consisting of: laser drilling and mechanical drilling.

28. The method according to claim 24,
wherein providing an electrically conductive material within the one or more holes comprises at least one of filling the one or more holes with electrically conductive material and growing electrically conductive material within the one or more holes.
